(19) United States
(12) Patent Application Publication
(10) Pub. No.: US 2006/0163745 A1
(43) Pub. Date: Jul. 27, 2006

(54) Semiconductor device

(76) Inventors: Shiro Yamashita, Fujisawa (JP); Daisuke Tsuji, Noshiro (JP); Akihiko Hatasawa, Akita (JP); Hidehiro Takeshima, Akita (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/340,562

(22) Filed: Jan. 27, 2006

(30) Foreign Application Priority Data
Jan. 27, 2005 (JP) 2005-019446

(51) Int. Cl. H01L 23/48; H05K 1/16

(52) U.S. Cl. 257/773; 174/260; 257/734

(57) ABSTRACT

In a semiconductor device according to the present invention, a first bare chip, and a second bare chip having a wider principal surface than that of the first bare chip are connected to one principal surface and the other principal surface of an interposer substrate, respectively. In the semiconductor device, a resin having a larger coefficient of linear expansion than that of the second bare chip is applied to a backgrind surface (a principal surface at an opposite side to the interposer substrate) of the second bare chip, thereby preventing the second bare chip from cracking due to warpage of the interposer substrate.

The present application claims priority from Japanese application JP2005-019446 filed on Jan. 27, 2005, the content of which is hereby incorporated by reference into this application.

### BACKGROUND OF THE INVENTION

1. Field of the Invention

The present invention relates to a mounting construction of a semiconductor device typified by a multi-chip module in which a plurality of semiconductor chips are connected to two sides of an interposer substrate.

2. Description of the Related Art

Miniaturization and high function promotion of mobile products such as a mobile phone and personal digital assistants (PDA) have progressed. According to Non-patent document 1, for example, which will be described later, a multi-chip module in which a plurality of chips are mounted in one package and a system in package (SIP) have progressed in development as a mounting technique able to cope with these demands. FIG. 1 shows an example of the SiP. This package includes three chips (e.g., semiconductor integrated circuit devices) 1 which are mounted on respective substrates 3 each having solder bumps 2. The chip 1 is fixed to one principal surface of the substrate 3 with non-conductive paste (NCP) 7. Other two substrates 3 are fixed to the other surface of the substrate 3. The chips 1 are fixed to the other two substrates 3 with silver (Ag) paste 5. Electrodes and wiring patterns (not shown) formed on the respective principal surfaces of the two substrates are electrically connected to the chips (chip electrode) 1 through bonding wires 6 made of a conductor. The substrate 3 (having the widest principal surface among the three substrates) shown in a lower side of FIG. 1 functions as the so-called interposer substrate which is sandwiched between the chips 1 disposed on the both sides thereof. In order to cope with the demand for further miniaturization and thinning of the package, a construction is studied in which the chips 1 are directly mounted on the two sides of the interposer substrate 3.

The construction in which bare chips 1a and 1b are mounted on the two sides of the interposer substrate (hereinafter also referred as “the interposer” in some cases) 3 is shown in FIG. 2. With the construction, when the constructions of the two sides of the interposer 3 are asymmetrical (e.g., the bare chips 1a and 1b are different in size, shape and number from each other with respect to the two sides of the interposer 3), the module is deformed due to a thermal load during the mounting, so that the reliability in connection between the chip electrodes and the substrate electrodes is reduced. For example, there is such a shortcoming that cracks are generated in the bare chip when the bare chip is thin. For example, Patent document 1 which will be described below disclosed that a total sum of flexural rigidities of a chip, a substrate, a resin for connection, and the like as constituent materials of a module is controlled for improvement in reliability.

### [Patent Document 1] JP-A 10-229102

[Non-patent document 1 ] Haruo Shimamoto, “Package Technology in Renesas Technology Corp., Strategies for Mounting Developments and Development in 2004,” (The collected papers of Semiconductor Technology Solutions Symposium The 2nd. titled “Semiconductor Package Technology Supporting Information Household Electrical Appliances, Strategies for Mounting Developments and Development in 2004 of Companies” (Murakami et al.), published in December, 2003 by IDUSTRY AND SCIENCE SYSTEMS CO., LTD. (Tokyo, Japan), pages 49 to 64)

### SUMMARY OF THE INVENTION

FIG. 2 shows the construction of the module described above. In this construction, large and small two bare chips are connected to the two sides (e.g. front and rear sides) of the interposer 3 with a non-conductive paste (NCP) material 7. A chip A(1a) smaller than a chip B(1b) connected to a lower surface side (a lower surface of the interposer 3 in FIG. 2) of the module is connected to an upper side of the module, i.e., a side (an upper surface of the interposer 3 in FIG. 2) having no solder connection portion for connection to a secondary mounting board (e.g., another printed circuit board (not shown)). These chips A and B (both of them are the bare chips) are 0.15 mm in thickness, and the interposer substrate is 0.26 mm in thickness. When this module is manufactured, the large chip B(1b) is connected to the lower surface of the interposer 3, and then the small chip A(1a) is connected to the upper surface of the interposer 3.

When the module is cooled after the small chip A(1a) is connected to the upper surface of the interposer 3 (after a series of soldering processes are completed), the interposer 3 tends to more largely contract than the chips 1a and 1b contract because a coefficient of linear expansion of the interposer 3 is larger than that of each of the chips 1a and 1b. At this time, since the chip B(1b) connected to the interposer 3 exerts a large influence on the interposer 3, the module is warped so as to project to the lower side (so that the small chip A(1a) is surrounded by the interposer 3). At this time, the chip A(1a) mounted to the upper surface of the interposer 3 will avoid such warpage of the module (the interposer 3) due to the chip B(1b). To this end, a large stress is generated in a backgrind surface (a surface to which backgrinding is applied) of the chip B(1b) along the projection of an external contour of the chip A(1a) thereto. As a result, cracks are generated in the chip B(1b).

In order to solve the above-mentioned problems, the present invention provides a semiconductor device (multi-chip module) comprising a wiring board (interposer) having a first principal surface thereof to which a first semiconductor element (chip) is connected with a resin material, and a second principal surface thereof opposite to (facing) the first principal surface to which a second semiconductor element (chip) having a larger area (with respect to one of the first and second principal surfaces) than that of the first semiconductor element is connected with a resin material, wherein a resin material is applied to a surface as well at an opposite side to another surface (a surface facing the second principal surface) of the second semiconductor element connected to the wiring board with the resin material. For example, a back surface of the semiconductor element when viewed from the wiring board is also covered with the resin material. Non-conductive paste (NCP), for example, is used as the resin material.

When the second semiconductor element are electrically connected to electrodes or a wiring pattern formed on the wiring board through electrodes formed on the surface facing the second principal surface of the wiring board, the resin material is applied to the surface of the second semiconductor element at an opposite side to the surface thereof with which the electrical connection to the wiring board is made.

The above-mentioned semiconductor device (its mounting construction) according to the present invention is effective when for example, a thickness of the wiring board is equal to or smaller than 0.3 mm, and a thickness of the first semiconductor element is equal to or smaller than 0.2 mm. Moreover, the semiconductor device according to the present invention is effective when a length of one side of the wiring board is equal to or larger than 8 mm, and a length of one side of the first semiconductor element is equal to or smaller than 4 mm. A plurality of wiring layers may be formed on the printed wiring board concerned.

FIG. 3 exemplifies a construction of the semiconductor device thus described according to the present invention. In this construction, a resin having a larger coefficient of linear expansion than that of a chip B(1b) is applied to a backgrind surface (i.e., a principal surface at an opposite side to the wiring board) of the chip B(1b) connected to a lower surface of the module.

According to the present invention, during cooling after connection of a chip A(1a), a resin (7a) applied to the backgrind surface of the chip B(1b) further contracts than the chip B(1b) contracts. For this reason, the deformation of the module which tends to warp to the lower surface side is suppressed. As a result, it is possible to reduce a stress generated in the backgrind surface of the chip B(1b), and it is possible to prevent the chip B(1b) from being cracked. Consequently, it is possible to manufacture the multi-chip module having the construction in which bare chips different in size from each other are connected to the two sides of the interposer.

### BRIEF DESCRIPTION OF THE DRAWINGS

FIG. 1 is a schematic cross sectional view showing a mounting construction of a SiP in a prior art;

FIG. 2 is a schematic cross sectional view of a module having a construction which the inventors of the present invention firstly investigated and in which two thin bare chips different in size from each other are connected to two sides of an interposer;

FIG. 3 is a schematic cross sectional view of a module having a construction which the inventors of the present invention has investigated and in which two thin bare chips different in size from each other are connected to the two sides of the interposer, respectively, and a resin is applied to a backgrind surface of a chip B;

FIG. 4 is a schematic cross sectional view of a module construction with which simulation analysis is performed, and a diagram (table) in which sizes of the module constructions are arranged with respect to a semiconductor module according to an embodiment of the present invention;

FIGS. 5(a) to 5(c) are diagrams showing an example of a model with which simulation analysis is performed with respect to the semiconductor module according to the embodiment of the present invention;

FIG. 6 shows a table in which values on physical properties of materials are arranged which are used when simulation analysis is performed with respect to the semiconductor module according to the embodiment of the present invention;

FIGS. 7(a) to 7(c) are views in which calculation results obtained based on simulation analysis on the module constructions described from a model (1) to a model (3) shown in FIG. 4, and values of maximum principal stresses generated in backgrind surfaces of chips (B) are collectively shown with respect to the semiconductor module according to the embodiment of the present invention;

FIGS. 8(a) to 8(c) are views in which calculation results obtained based on simulation analysis on the module constructions described from a model (4) to a model (6) shown in FIG. 4, and values of maximum principal stresses generated in backgrind surfaces of chips (B) are collectively shown with respect to the semiconductor module according to the embodiment of the present invention;

FIGS. 9(a) to 9(c) are views in which calculation results obtained based on simulation analysis on the module constructions described from a model (7) to a model (9) shown in FIG. 4, and values of maximum principal stresses generated in backgrind surfaces of chips (B) are collectively shown with respect to the semiconductor module according to the embodiment of the present invention;

FIGS. 10(a) to 10(c) are views in which calculation results obtained based on simulation analysis on the module constructions described from a model (10) to a model (12) shown in FIG. 4, and values of maximum principal stresses generated in backgrind surfaces of chips (B) are collectively shown with respect to the semiconductor module according to the embodiment of the present invention;

FIG. 11 is an external appearance observation photograph showing cracks which are generated in chip B after a sample having no NCR material on a backgrind surface of the chip B is made with respect to the semiconductor module according to the embodiment of the present invention; and

FIGS. 12(a) and 12(b) are schematic cross sectional views showing examples of changes (variations) of the semiconductor module according to the embodiment of the present invention.

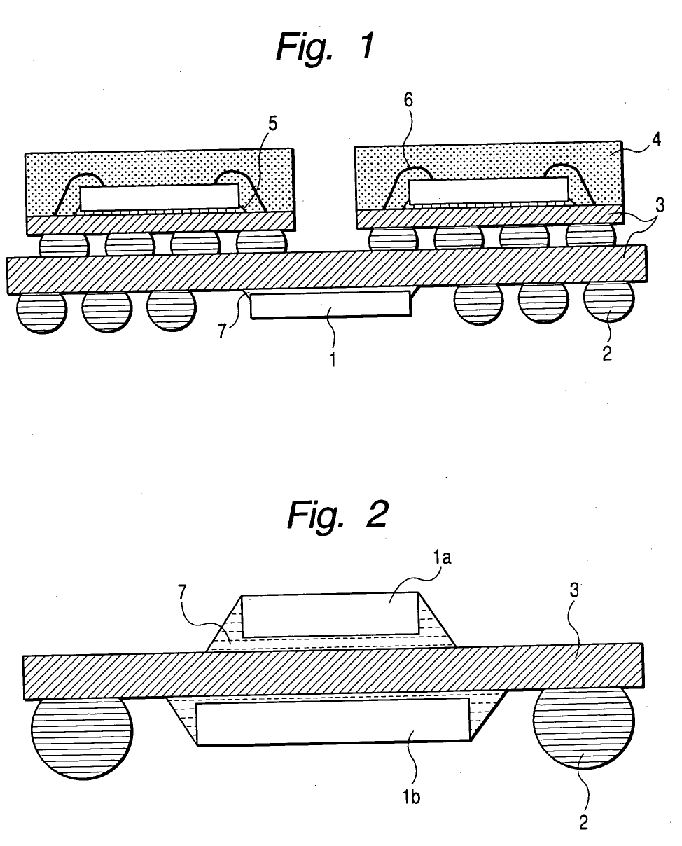

### DETAILED DESCRIPTION

Hereinafter, an embodiment of the present invention will be described based on the accompanying drawings. Firstly, a relation between generation of cracks in a chip and a module construction was investigated by using simulation analysis.

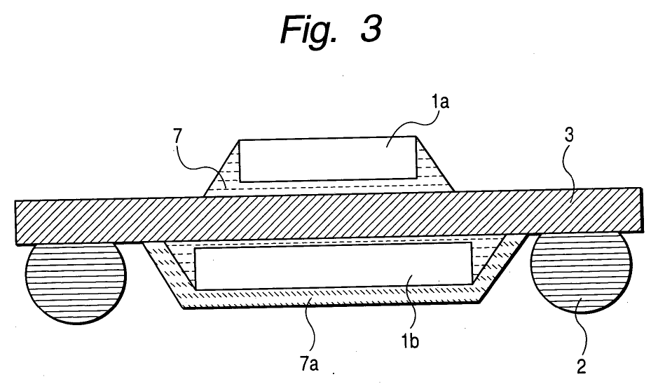

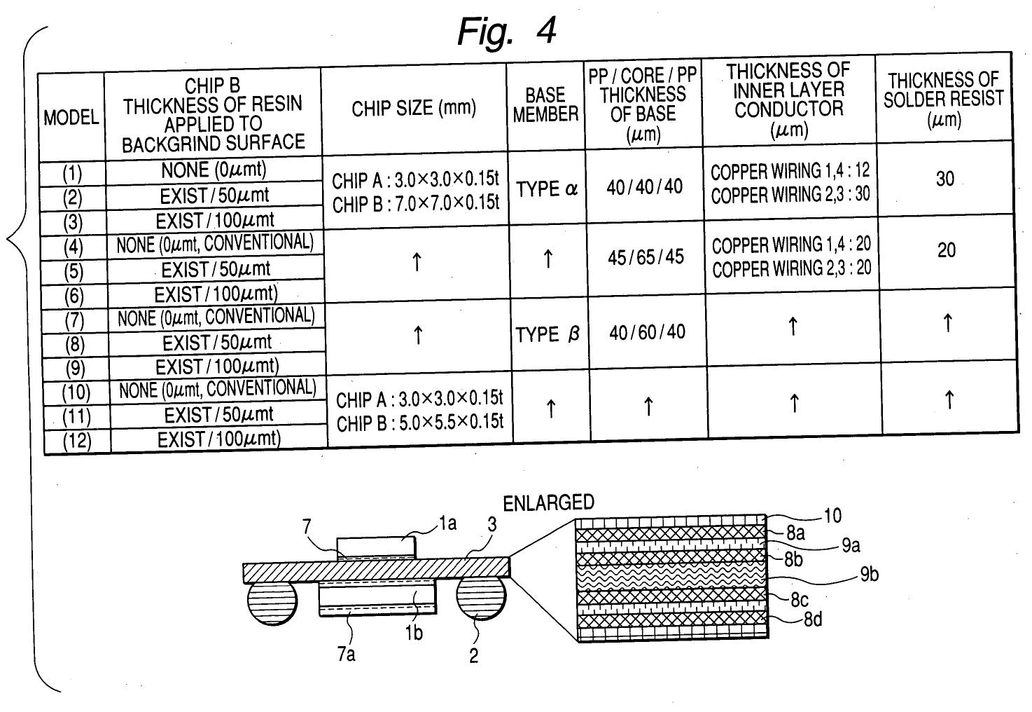

A semiconductor device (module), shown in FIG. 3, including ones each having no resin material 7a formed on a back surface (a surface at an opposite side to a wiring board 3: hereinafter referred to as “a backgrind surface”) of a chip B(1b) was used as a model for simulation analysis. As a result, it has been found that cracks in the chip B(1b) were generated in the backgrind surface. In the light of this, the inventors of the present invention derived a maximum principal stress generated in the chip B(1b). FIG. 4 shows detailed data of various kinds of constructions which were investigated this time.

Simulation analysis was performed with respect to twelve kinds of models. In the twelve kinds of models, base members 9a and 9b of wiring boards 3 (hereinafter referred to as “interposer substrates”) were different in thickness from one another, copper wirings 8a to 8d as inner layer conductors were different in thickness from one another, solder resists 10 formed on respective principal surfaces of the interposer substrate 3 were different in thickness from one another, and resin materials 7a formed on respective backgrind surfaces of the chips B(1b) were different in thickness from one another. The reference numeral 1 of the copper wiring, reference numeral 2 of the copper wiring, reference numeral 3 of the copper wiring, and reference numeral 4 of the copper wiring correspond to reference numerals 8a, 8b, 8c and 8d, respectively. The base member includes a core 9b, and prepregs 9a (described as PP in FIG. 4: a material subjected to preimpregnation) which are disposed on the upper and lower sides of the core 9b.

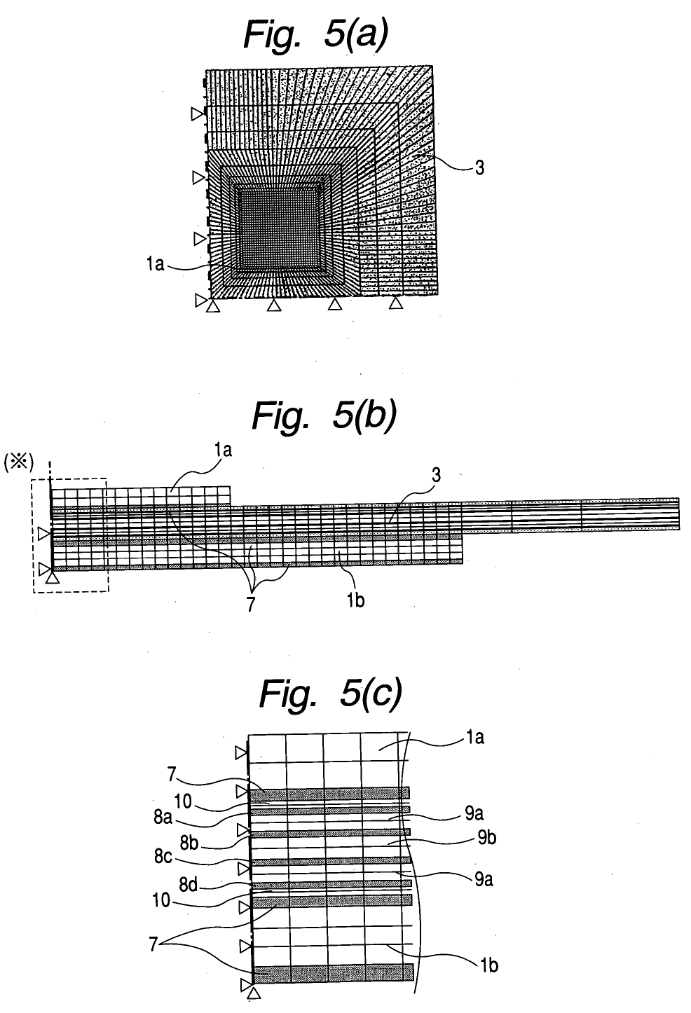

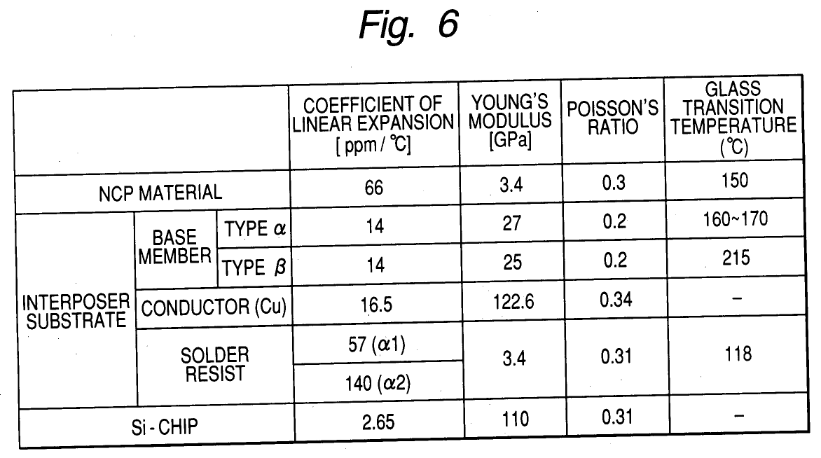

FIGS. 5(a) to 5(c) show an example of an analysis model which was used this time. Of these figures, FIG. 5(c) is an enlarged view of a portion (※) shown in FIG. 5(b). It was assumed for simplification of the consideration, that each of the base member, the copper wiring, and the solder resist was formed in a sheet-like shape without provision of a corresponding pattern. In addition, a resin applied to the backgrind surface of the chip B(1b) was assumed to be a non-conductive paste material (hereinafter referred to as “an NCP material”) with which the chip and the interposer were connected to each other. FIG. 6 shows values of material constants. An initial temperature value in analysis temperature conditions was set at 150° C. as a glass transition temperature. Thus, a value of the maximum principal stress which was generated in the backgrind surface of the chip B when the temperature was dropped to a room temperature, 25° C. was derived. In addition, the chips were assumed to be connected to the center of the interposer, and a ¼ model was used. A fillet of the NCP material was omitted.

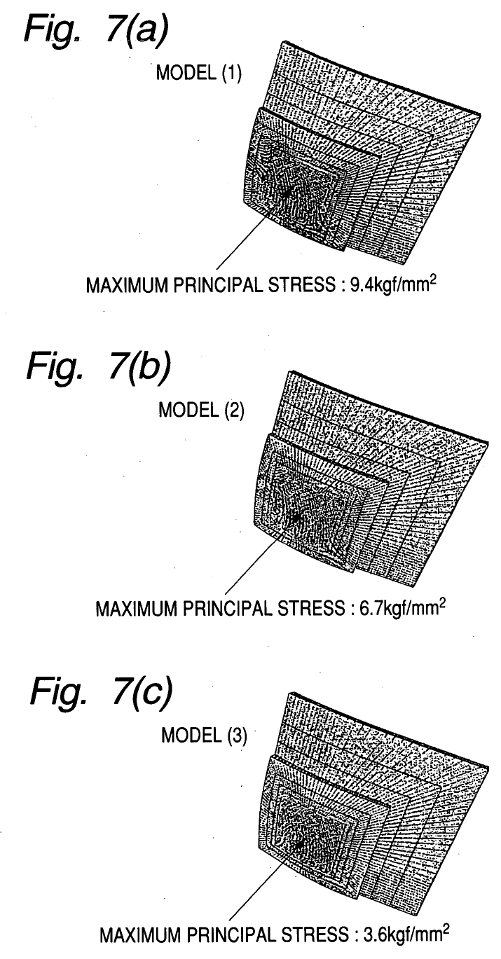

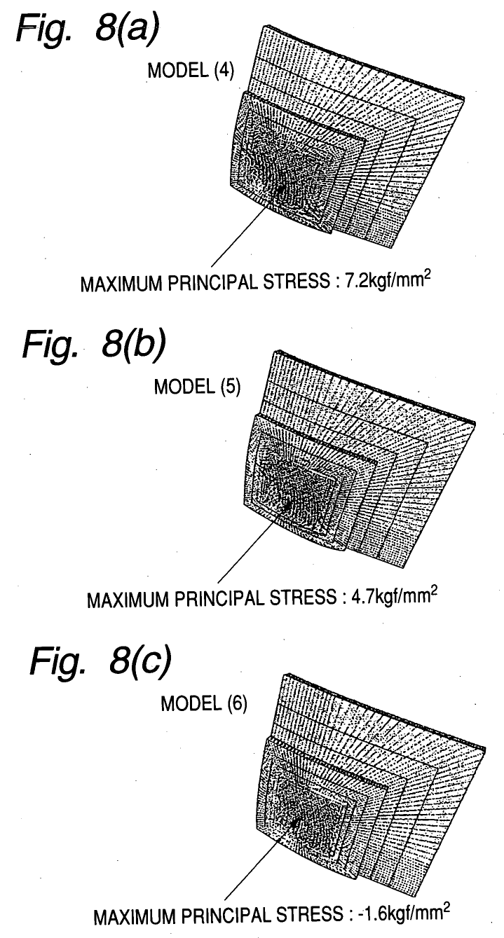

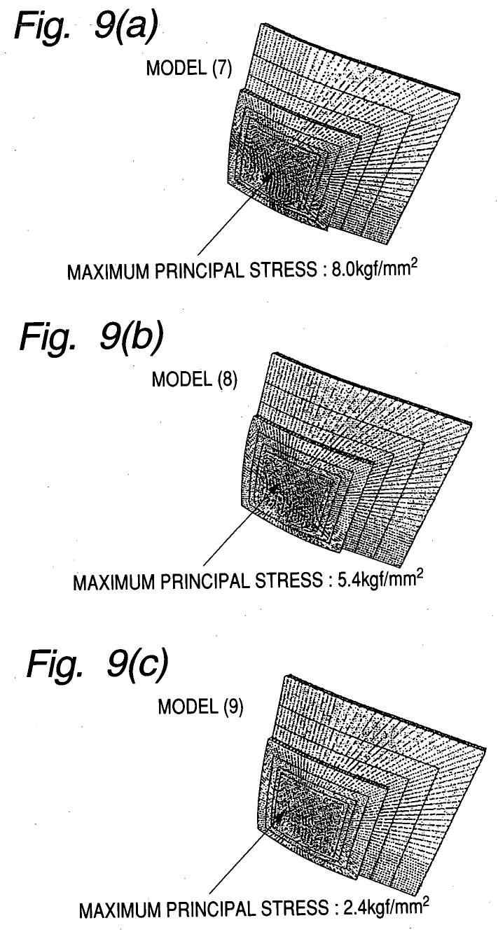

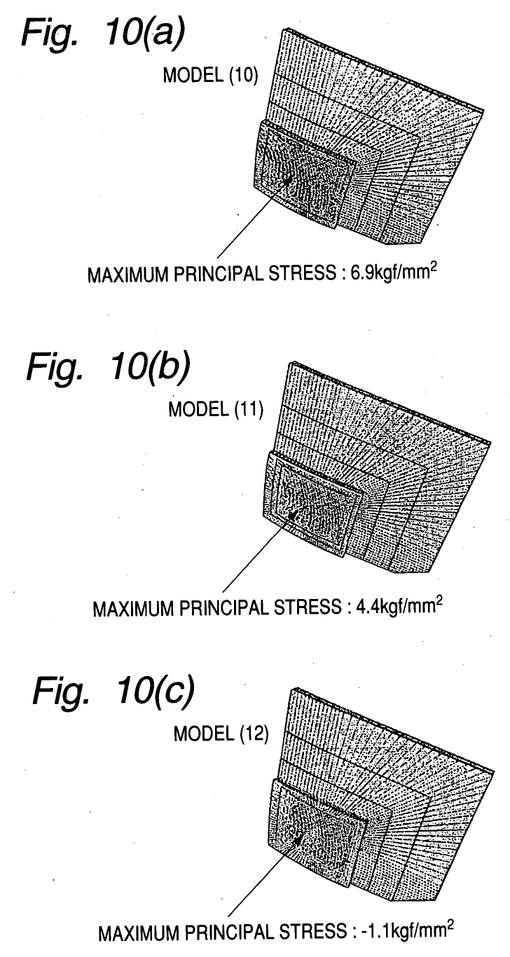

FIGS. 7(a) to 10(c) show the analysis results of the simulation described above for twelve kinds of models which are enumerated in Table shown in FIG. 4. In FIGS. 7(a) to 7(c), FIGS. 8(a) to 8(c), FIGS. 9(a) to 9(c), and FIGS. 10(a) to 10(c), the simulation results for every three models in which the thicknesses of the base members 9a and 9b of the interposer substrate 3, the thicknesses of the copper wirings 8a to 8d as the inner layer conductors, and the thicknesses of the solder resists 10 formed on the respective principal surfaces of the interposer substrates 3 are equalized, respectively, are shown in the order of (a) to (c) in association with the thicknesses of the resins applied to the respective backgrind surfaces of the chips B. The maximum principal stress generated in the backgrind surface of the chip B in the case of the construction ((b) or (c)) having the resin applied to the backgrind surface of the chip B greatly decreased as compared with the case of the construction (a) having no resin. In addition, the maximum principal stress in the case (c) where the thickness of the resin was 100 μm was smaller than that in the case (b) where the thickness of the resin was 50 μm. Consequently, it was found out that the chip B in the case of the construction having the resin applied to the backgrind surface of the chip B hardly cracked as compared with the case of the construction having no resin, and the chip B hardly cracked as the thickness of the resin was further increased.

Next, the samples were actually made in order to check whether or not the chips B cracked. Investigation was made with respect to two kinds of module constructions, i.e., the module construction in which the resin was applied to the backgrind surface of chip B, and the module construction in which no resin was applied thereto. The chip size, the size of the interposer substrate, the thickness of the base member, the thickness of the copper wiring as the inner layer conductor, the thickness of the solder resist, and the like in this case were made equal to those in the case of the simulation analysis. When the sample was made, firstly, the chip B was connected to the interposer substrate with the NCP material. In this connection process, the NCP material was heated in a state in which a temperature of 220° C. or more was maintained for three seconds so as not to exceed a maximum temperature of 225° C. Thus, the chip B was connected to the interposer substrate. For the sample having the construction in which the resin was formed on the backgrind surface of the chip B, the NCP material was applied to the backgrind surface, and heated and cured under the same conditions as those described above. Finally, for all the samples, the chips A were fixed to the respective interposer substrates by heating the NCP materials under the same conditions as those for the fixing of the chips B to the respective interposer substrates with the NCP materials described above. Thereafter, the interposer substrates were heated in a state in which a temperature of 220° C. or more was maintained for 30 seconds so as not to exceed a maximum temperature of 245° C. Thus, solder bumps were formed on the respective interposer substrates and it was visually observed whether or not the chips B were cracked.

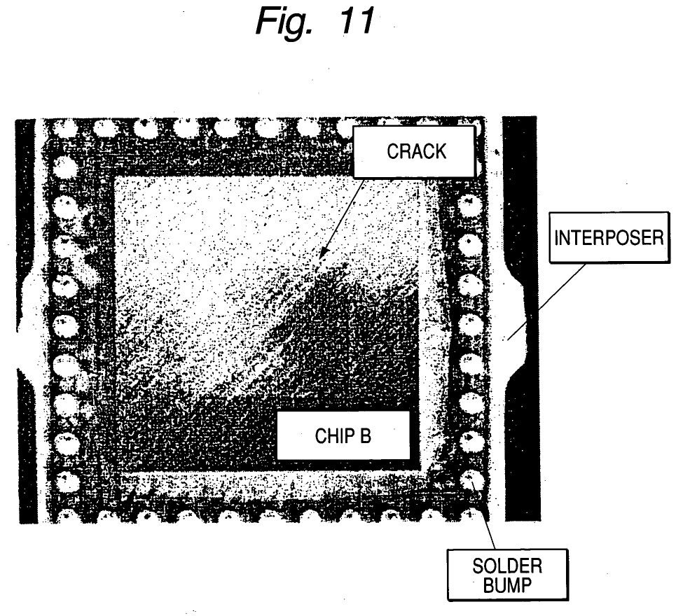

In the case of the samples each having the construction in which no resin is formed on the backgrind surface of the chip B, the chips B cracked in 6 samples of the 57 samples thus made. FIG. 11 shows external appearance observation results of the cracked sample. On the other hand, in the case of the samples each having the construction in which the resin is formed on the backgrind surface of the chip B, the chips B did not crack in all the samples of 50 samples thus made.

Such a tendency takes place when the thickness of the interposer substrate is equal to or smaller than 0.3 mm, and the thickness of the chip A mounted on the principal surface (first principal surface) at an opposite side to the surface (second principal surface), on which the chip B is mounted, of the interposer substrate is equal to or smaller than 0.2 mm. For example, when the thickness of the interposer substrate becomes less than 2 times as large as that of the chip A as the interposer substrate is thinned, a stress is readily applied from an end portion of the chip A to the principal surface of chip B through the interposer substrate. In addition, such a tendency also takes place when a length of one side of the interpose substrate is equal to or larger than 8 mm, and a length of one side of the chip A is equal to or smaller than 4 mm. That is to say, the stress is readily applied from the end portion of the chip A to the principal surface of the chip B through the interposer substrate as the length of one side of the chip A along one side extending in a certain direction of the interposer substrate becomes shorter with respect to the one side extending in the certain direction of the interposer substrate. From this fact, for example, when a length of one side extending in a certain direction of the chip A becomes equal to or smaller than half the length of the one side extending in the certain direction of the interposer substrate, the mounting construction of the semiconductor device according to the present invention remarkably suppresses a probability of generation of cracks in the backgrind surface of the chip B.

While not illustrated in FIG. 11, electrodes may be formed on a surface of the chip B facing the principal surface of the interposer substrate in order to be electrically connected to electrodes or a wiring pattern formed on the principal surface concerned of the interposer substrate. At this time, the material with which the chip B and the interposer substrate are connected to each other is not limited to the resin material covering the backgrind surface of the chip B. Thus, for example, an anisotropic conductive film may also be used as that material.

From the foregoing, the use of the present invention makes it possible to manufacture the multi-chip module having the construction in which the bare chips different in size from each other are connected to the two sides (e.g. front and rear sides) of the interposer substrate.

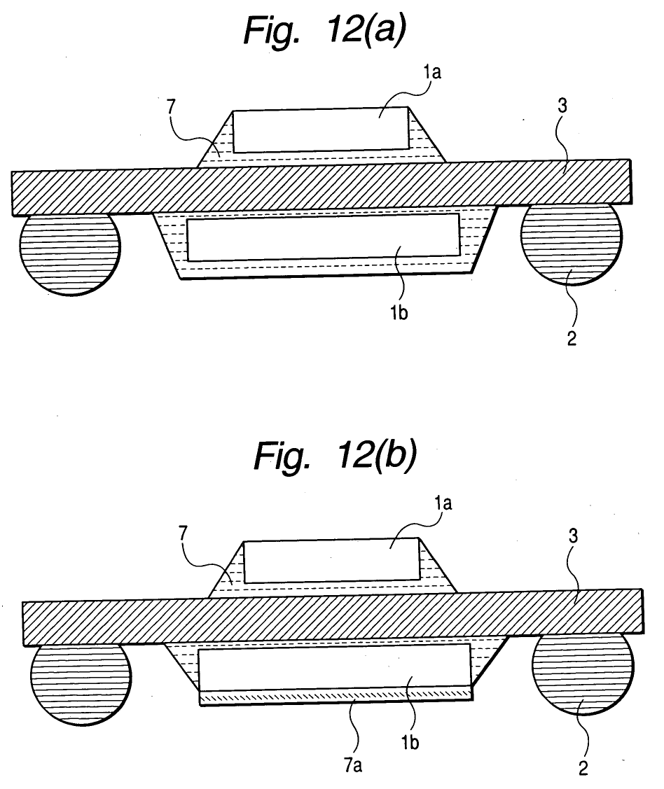

In addition, the multi-chip module can be manufactured even in the construction shown in FIGS. 12(a) and 12(b). The NCP material with which the chip is connected to the interposer as made in the embodiment is used as the resin applied to the backgrind surface of the chip B, or the resin film is bonded to the backgrind surface of the chip B, whereby the chip B can be prevented from cracking.

When the multi-chip module is manufactured, the bare chips are purchased from other companies in order to be assembled for manufacture in many cases. Thus, such a technique that the chips different in size from each other are connected to the two sides of the interposer will be used more and more frequently in future. The present invention provides the module construction which is effective in such a connection system.

While we have shown and described several embodiments in accordance with the present invention, it is understood that the same is not limited thereto but is susceptible of numerous changes and modifications as known to those skilled in the art, and we therefore do not wish to be limited to the details shown and described herein but intend to cover all such changes and modifications as are encompassed by the scope of the appended claims.

What is claimed is:

1. A semiconductor device comprising a construction in which in a multi-chip module having a semiconductor element connected to one surface of a wiring board with a resin material, and another semiconductor element connected to the other surface of said wiring board with a resin material, said another semiconductor element having an area larger than that of said semiconductor element, a resin material is also applied to a surface, of said another semiconductor element having the larger area, at an opposite side to a surface of said another semiconductor element connected to said wiring board with the resin material.

2. A semiconductor device comprising a construction in which in a multi-chip module having a chip connected to one surface of a wiring board with a resin material, and another chip connected to the other surface of said wiring board with a resin material, said another chip having an area larger than that of said chip, a resin material is also applied to a surface, of said another chip having the larger area, at an opposite side to a surface of said another chip connected to said wiring board with the resin material.

3. The semiconductor device according to claim 2, wherein in said multi-chip module having said chip having a thickness of 0.2 mm or less connected to the one surface of said wiring board having a thickness of 0.3 mm or less with the resin material, and said another chip connected to the other surface of said chip, said another chip having an area larger than that of said chip, said resin material is also applied to the surface, of said another chip having the larger area, at the opposite side to the surface of said another chip connected to said wiring board with the resin material.

4. The semiconductor device according to claim 3, wherein in said multi-chip module having said chip having a thickness of 0.2 mm or less connected to the one surface of said wiring board having a thickness of 0.3 mm or less and having a plurality of wiring layers with the NCP material, and said another chip connected to the other surface of said chip with the NCP material, said another chip having an area larger than that of said chip, said resin material is also applied to the surface, of said another chip having the larger area, at the opposite side to the surface of said another chip connected to said wiring board with the NCP material.

5. The semiconductor device according to claim 4, wherein in said multi-chip module having said chip having a thickness of 0.2 mm or less connected to the one surface of said wiring board having a thickness of 0.3 mm or less and having a plurality of wiring layer with the NCP material, and said another chip connected to the other surface of said chip with the NCP material, said wiring board having a side length of 8 mm or more, said chip having a side length of 4 mm or less, said another chip having a larger area than that of said chip, said resin material is also applied to the surface, of said another chip having the larger area, at the opposite side to the surface of said another chip connected to said wiring board with the NCP material.
